(19) United States
(12) Patent Application Publication
(10) Pub. No.: US 2025/0273756 A1
(43) Pub. Date: Aug. 28, 2025

(54) SYSTEM, METHOD, AND APPARATUS FOR GAS EMISSIONS LOCATOR AND BATTERY SELF-ISOLATION

(71) Applicant: SAUDI ARABIAN OIL COMPANY, Dhahran (SA)

(72) Inventors: Rami A. Al-Ghanim, Dhahran (SA); Abdullah Y. Al-Hassan, Dhahran (SA); Fayaz S. Alanzi, Dhahran (SA); Abdullah W. Hamam, Dhahran (SA)

(73) Assignee: SAUDI ARABIAN OIL COMPANY, Dhahran (SA)

(21) Appl. No.: 18/589,126

(22) Filed: Feb. 27, 2024

(51) Int. Cl. H01M 10/48; F24F 7/06; F24F 11/70; F24F 110/65; G01R 31/3835; H02J 7/00

(52) U.S. Cl. CPC H01M 10/482; F24F 7/06; F24F 11/70; G01R 31/3835; H02J 7/0031; H02J 7/007188; F24F 2110/65; H01M 2220/10

(57) ABSTRACT

A method is disclosed for managing and safeguarding a battery environment. The method includes continuous monitoring of individual battery voltages in a battery room and automatic isolation of defective batteries, employing a controller-solenoid switch mechanism responsive to voltage abnormalities. The methodology accounts for the state of battery charging, invoking fan activation when charging occurs or hydrogen levels rise. Also disclosed is a system for managing a battery system in a battery room and isolating defective batteries. Enhanced system features include hydrogen sensors strategically placed throughout, including the ceiling, with outcome-driven fan operation and comprehensive notification mechanisms to inform on-site personnel of gas release locations, maintaining a secure and efficient battery room environment.

### FIELD OF THE DISCLOSURE

The present invention relates to safety and management systems for industrial facilities, and more particularly to an improved system, method, and apparatus dedicated to the proactive location of gas emissions and the automated isolation of batteries in battery rooms.

### BACKGROUND OF THE DISCLOSURE

Complex IT installation often require a large number of batteries for backup power and other uses. The batteries are usually stored in banks in rooms specifically allocated for them. The batteries utilized can include lead-acid batteries which have an associated serious safety hazard. Wet-cell lead-acid batteries release hydrogen (H₂) gas during charging processes. Released hydrogen can accumulate in the room and lead to a destructive explosion in the absence of proper ventilation due to the fact that hydrogen gas is highly flammable.

The necessity for reliable backup power in complex IT installations has fostered the widespread use of battery banks, often composed of lead-acid batteries. While these batteries are integral to ensuring continual operation, they inherently pose a risk due to the evolution of hydrogen gas, especially during the charging cycle. The colorless, odorless, and tasteless nature of hydrogen gas compounds the danger it presents, making it undetectable by human senses and potentially leading to hazardous accumulations that can cause explosive environments.

The present disclosure addresses the needs for improved safety in backup power systems for complex IT installations by providing a heretofore unavailable integrated system and method.

### SUMMARY OF THE DISCLOSURE

The disclosure herein is well-positioned to revolutionize safety protocols by incorporating proactive monitoring, automatic battery isolation, real-time hydrogen level assessment, and emergency response activation to significantly mitigate the risks associated with hydrogen gas in battery storage facilities. Further, the present disclosure provides a system to augment ventilation capacity proactively during the charging process or when hydrogen concentrations approach hazardous levels.

A method of managing a battery system in a battery room is disclosed. In one or more embodiments, this method includes continuously monitoring a voltage condition of individual batteries within the battery system. A defective battery cell is automatically isolated from the battery system upon detection of abnormal voltage levels through a controller. Upon detection, the controller sends a signal to a solenoid switch to change the connection from a first to a second connection, to isolate the defective battery from adjacent batteries. The isolation of the defective battery is executed based on the abnormal voltage levels sensed by a voltmeter sensor attached to the respective battery. The sensor communicates detected abnormalities to the controller. The controller interfaces with the solenoid switch.

In some embodiments, the method further involves detecting a hydrogen concentration in the battery room. The method involves determines whether the hydrogen gas concentration is at or above a first threshold concentration. Two or more exhaust fans are activated to ventilate the battery room simultaneously when the hydrogen gas concentration is at or above the first threshold. In further aspects, the method includes identifying a location in the battery room where hydrogen is being released. It determines whether the hydrogen gas concentration is at or above a second threshold, higher than the first threshold. Charging of batteries in the battery room is halted when the hydrogen gas concentration is at or above the second threshold. The two or more exhaust fans operate one at a time when the hydrogen gas concentration falls below the first threshold.

In further implementations, the method includes conducting a diagnostic check to validate the functionality of the solenoid switches upon isolation of a defective battery. In some implementations, the diagnostic check confirms that the solenoid switch has successfully changed from the first connection to the second connection to isolate the defective battery.

In yet further implementations, the controller comprises one or more redundancy systems, and in the event of a failure of the primary controller, the redundancy system maintains the capability to detect abnormal voltage levels and execute the isolation of defective batteries. This ensures continuous operation of the isolation feature.

In still further aspects, the method also includes conducting periodic voltage level assessments on adjacent batteries to the isolated defective battery. These assessments determine whether the isolation of the defective battery has impacted the functioning of adjacent batteries. The assessments are recorded to facilitate proactive maintenance and minimize the risk of subsequent battery failures.

In yet more variations, the method further involves determining whether any batteries in the battery room are currently being charged. If the batteries are being charged or the hydrogen gas concentration is at or above the first threshold, the two or more exhaust fans are activated to ventilate the battery room simultaneously. In some aspects, the method also includes activating at least one of a sound and a visual alert when the hydrogen gas concentration is at or above the first threshold. This warning is to prevent personnel from entering the battery room.

In some implementations of the method, features incorporated in the method indicate the battery room contains a plurality of battery banks and a plurality of hydrogen sensors. At least one of the plurality of hydrogen sensors is positioned at gas outlets of each of the battery banks. The location at which hydrogen is being released is determined based on which hydrogen sensor detects an elevated hydrogen concentration. In one or more variations, the plurality of hydrogen sensors includes a ceiling sensor. Determining whether the hydrogen gas concentration is at a first threshold includes detecting that concentration at two of the hydrogen sensors at the battery banks' gas outlets or at one of those sensors and the ceiling sensor.

Additionally, in some aspects, the method further comprises generating a notification when the hydrogen gas concentration is at or above the first threshold. This notification is provided to personnel. In further aspects, the notification indicates the identified location in the battery room where hydrogen is being released.

Also disclosed is a system for managing a battery system in a battery room and isolating defective batteries. In one or more embodiments, the system comprises a plurality of battery banks positioned in the battery room containing one or more batteries. A controller is configured to monitor the voltage of individual batteries within the battery banks. The system includes a plurality of solenoid switches, each connected to at least two batteries. A plurality of voltmeter sensors are associated with a respective battery and coupled to the controller. A control system is coupled to the controller and to the solenoid switches to aid in isolating a defective battery. The controller is operative to receive output from the voltmeter sensors indicating a voltage condition of each battery. The controller sends a signal to respective solenoid switches to isolate a defective battery by changing the connection between the defective battery and adjacent batteries if an abnormal voltage is detected.

In one or more implementations, the system has a plurality of exhaust fans positioned in the battery room. A plurality of hydrogen sensors, with at least one sensor positioned adjacent to each one of the plurality of battery banks, are included in the system. A hydrogen detector is coupled to the plurality of hydrogen sensors. A monitoring device is coupled to the hydrogen detector and to the plurality of exhaust fans. The hydrogen detector is operative to receive output from the sensors and to generate a signal indicating a detected hydrogen concentration. The monitoring device is configured to operate a fan control system to activate two or more exhaust fans simultaneously upon receipt of a signal indicating that the hydrogen concentration is at or above a first threshold. This activation reduces the chance of hydrogen accumulation. If the battery isolation does not control the hydrogen level and it reaches 1% or more, the monitoring device activates the plurality of exhaust fans.

In further implementations, the system further includes diagnostic functionality in the control system for validating the operation of the solenoid switches upon isolating a defective battery. The diagnostic functionality confirms successful connection changes by the solenoid switch to isolate the defective battery. In yet further implementations, the system has a controller that includes one or more backup redundancy systems designed to take control in the event of a primary controller failure. The redundancy systems have circuitry and programming to detect abnormal voltage levels and control the solenoid switches for isolating defective batteries.

In some aspects, the system further includes voltmeter sensors to conduct voltage assessments on batteries adjacent to the isolated defective battery. The control system records the outcomes of these assessments. In additional aspects, the system also comprises a battery charger coupled to the monitor. The monitor operates the fan control system to activate exhaust fans simultaneously if a battery bank is being charged or if the hydrogen concentration is at or above the first threshold. In additional implementations, the fan control system activates the exhaust fans when the battery charger operates in a boost mode.

In further aspects of the system, the system includes a monitoring device configured to identify which battery bank releases hydrogen based on the output of the hydrogen detector when the concentration is at or above the first threshold. In additional aspects, the system also features at least one sound alarm and visual alarm near the entrance to the battery room. The monitoring device activates the alarm upon receipt of a signal indicating the hydrogen concentration is at or above the first threshold.

In yet more variations, the system includes a battery charger breaker coupled to the monitoring tool and the battery banks. The hydrogen detector outputs a signal indicating whether the concentration is at or above a second threshold higher than the first threshold. The monitoring device activates the battery charger breaker to halt the charging of the battery banks if the second threshold is reached. In select variations, the first threshold concentration is 1 percent by volume, and the second threshold is 2 percent by volume. In yet further variations, the system includes additional hydrogen sensors including a sensor on the ceiling of the battery room wherein the detector indicates that the concentration is at the first threshold if two sensors at the battery banks detect it or if one sensor at the banks and the ceiling sensor detect it.

In still further implementations, the system has a monitoring device configured to activate one exhaust fan at a time when the hydrogen concentration is below the first threshold. In various implementations, the system features a monitoring device configured to generate and provide notifications to personnel, including the identified location of hydrogen release.

These and other aspects, features, and advantages can be appreciated from the following description of certain embodiments of the invention and the accompanying drawing figures and claims.

### BRIEF DESCRIPTION OF THE DRAWINGS

FIG. 1 is a schematic block diagram of an exemplary embodiment of a system for managing a battery room and isolating defective batteries according to the present disclosure.

FIG. 2 is a schematic diagram of an embodiment of a circuit for switching from alternate to simultaneous fan operation according to the present disclosure and a legend identifying elements in the schematic diagram.

FIG. 3A is a schematic diagram of an exemplary battery and sensor deployment in a system for managing a battery room and isolating defective batteries according to the present disclosure.

FIG. 3B is an expanded view of a sub-system for monitoring batteries in a battery bank and isolating batteries exhibiting abnormal conditions according to an implementation of the present disclosure.

FIG. 4 is a flow chart of a method for managing a battery room and isolating defective batteries according to an embodiment of the present disclosure.

FIG. 5 is a circuit diagram of an exemplary embodiment of a system for isolating defective batteries in a battery bank according to the present disclosure.

### DETAILED DESCRIPTION OF CERTAIN EMBODIMENTS OF THE DISCLOSURE

The disclosure herein presents an integrated method and system for proactive management of battery systems and the mitigation of hydrogen gas risks within battery rooms. This comprehensive solution encompasses hydrogen gas detection, an exhaust fan system, and battery condition monitoring. As used herein, “batteries” and “battery cells” both generally refer to a housing with positive and negative connection terminals. In a series of battery rooms, each hosting multiple battery banks, the system oversees the status of individual batteries. The typical type of battery is a lead acid battery from one of several manufacturers. Examples of these manufacturers include but are not limited to those commercially available from EnerSys (e.g., under the tradename PowerSafe) (Reading, PA, USA), HOPPECKE Batteries (Hainesport, NJ, USA), and FIAMM Energy Technology (Montecchio Maggiore, Italy). A non-limiting exemplary voltage operating range for the batteries is between about 2.33 and about 2.18 volts during float charging (the normal condition for battery bank in communications rooms). A non-limiting exemplary internal resistance operating range for the batteries is no more than about 135% of the internal resistance baseline. A non-limiting exemplary internal temperature operating range for the batteries is between about 20 and about 40 degrees Celsius. A non-limiting exemplary specific gravity range for the batteries is between about 1.23 to about 1.25 kg/l.

Upon detecting abnormal battery voltage, the system autonomously isolates the affected battery through a control system, preventing significant hydrogen gas emission. This isolation is facilitated using a physical interface circuit, where solenoid switches manipulate connections between batteries based on voltmeter sensor readings managed by a programmable logic controller or “plc” (e.g., Arduino) controller.

In some embodiments, when hydrogen concentration reaches a critical level of 1% or more, dual fan activation occurs, and a centralized network operation center is alerted to deploy field technicians. The system's ventilation capabilities are augmented to hasten hydrogen dispersion. In the event of detection exceeding a 2% hydrogen concentration, further escalation protocols are initiated through computer or telephone network(s) to inform management. In doing so, the system disclosed herein integrates with a battery charge breaker, enhancing facility safety. The system returns to normal operations once safe conditions are restored-highlighting its dual-natured response by isolating batteries on voltage fluctuations and activating fans upon hydrogen detection.

The method and system disclosed herein builds upon and improves the reactive measures of preexisting solutions by focusing on preemptive controls that entirely neutralize a principal source of hydrogen emissions, ensuring an inherently safer environment, continued battery bank operation, and potentially reduced need for ventilation acceleration.

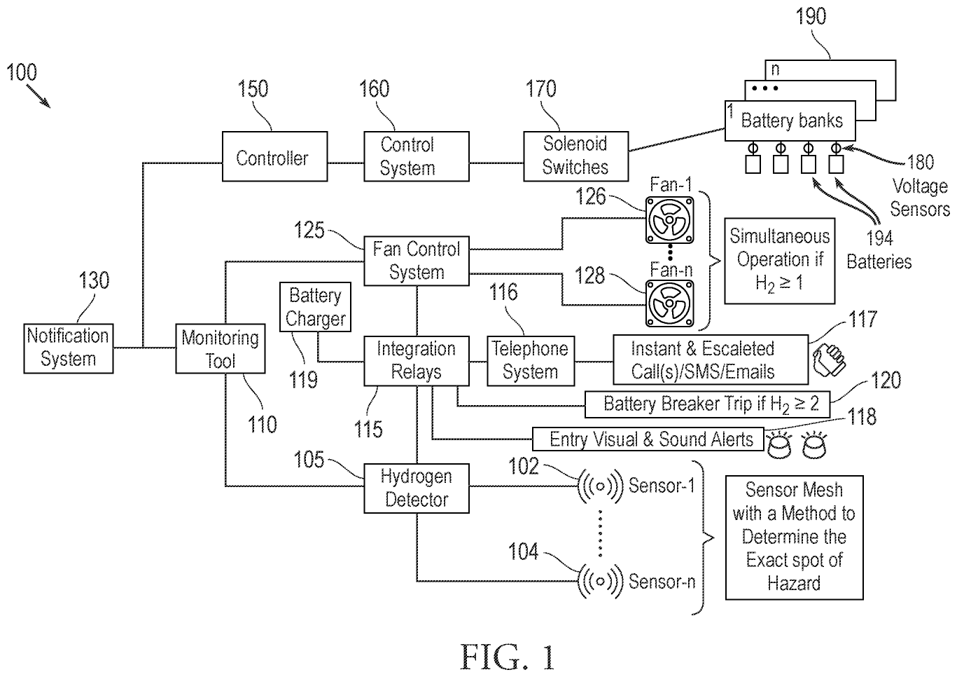

FIG. 1 is a schematic block diagram of an exemplary embodiment of a system for managing a battery room and isolating defective batteries according to the present disclosure. The system 100 is intended to be implemented within a battery room of a facility, such as an information technology (IT) facility in an organization. However, the system can be implemented at any location which is subject to hydrogen gas hazard risks. The battery room can enclose one or more flooded (wet) rechargeable lead-acid batteries or stacks thereof. While flooded lead-acid batteries have the advantage of rechargeability, during charging operations such batteries form and release hydrogen gas as result of hydrolysis reactions.

In some embodiments of the present disclosure, the system 100 depicted in FIG. 1 includes a sub-system for continuously monitoring a voltage condition of individual batteries 194 within a battery system. In various embodiments, this sub-system runs concurrently with a hydrogen ventilation system. In further embodiments, this sub-system runs in series with a hydrogen ventilation system.

The battery self-isolation sub-system includes a controller 150. In some implementations, this controller 150 is a programmable logic controller, oft referred to as a “plc” controller. An example of such a controller is an Arduino controller. In further aspects, the controller 150 contains a processor and is programmed to operate a control system 160. In some implementations, controller 150 contains a device driver that enables it to control the control system 160. In further implementations, the controller 150 is connected directly to solenoid switches 170, and the combination thereof serves as the control system for battery 194 isolation. In such a case, there is no separate control system 160.

In one or more implementations of the battery self-isolation sub-system, every battery 194 within a battery bank 190 or banks 190 that is/are monitored by the overall system is connected to solenoid switches 170. Consistent with a salient aspect of the present disclosure, the solenoid switches 170 are operable to open circuits connected to individual batteries within the battery banks 190. This serves the purpose of enabling isolation of defective batteries 194 within the battery banks 190. In some alternative implementations, bypass switches are used instead of or in conjunction with solenoid switches for battery isolation.

In one or more implementations, the battery self-isolation sub-system further includes voltmeter sensors electrically connected to each battery 194 within the battery banks 190. These voltmeter sensors serve the purpose of continuously monitoring a voltage condition of individual batteries within the battery system

There are many examples of battery failures that may give rise to abnormal voltage conditions. One example is corrosion: corrosion of the battery terminals or internal connections can increase the internal resistance of the battery, leading to reduced voltage output. A second example is sulfation: if a battery is left in a discharged state for an extended period, lead sulfate crystals can form on the plates, which can harden and reduce the battery's capacity, leading to lower voltage levels. A third example is overcharging: charging a battery for too long can cause excessive heat and lead to the breakdown of internal components, lowering the battery capacity and voltage output. A fourth example is undercharging: repeated undercharging can leave a battery with a chronic deficit of charge, affecting its ability to hold and deliver full voltage. A fifth example is short-circuiting: an internal short circuit, due to the breakdown of separator material or other causes, can lead to a rapid decrease in voltage and may cause overheating or even a fire. A sixth example is dry battery cells: loss of electrolyte, often in the form of water due to evaporation or overcharging (which causes the water to decompose), can lead to increased internal resistance and decreased voltage, as there is not enough liquid to facilitate the charge/discharge reactions. Additional examples include damaged lead plates, electrolyte imbalances, temperature extremes, age/wear, and cell polarity reversal, among others.

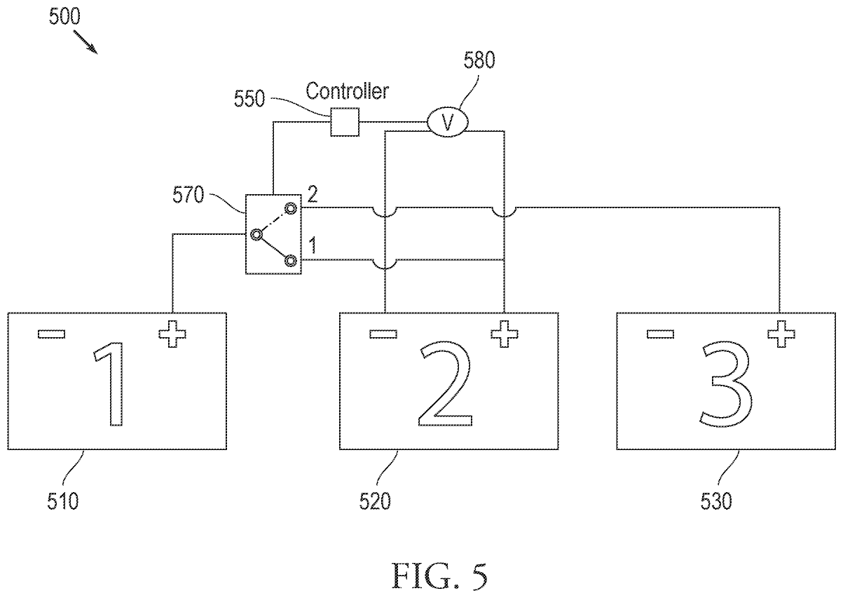

The voltmeter sensors 180 are electrically connected to the controller 150, which is programmed to monitor abnormal voltage conditions or parameters and to interface with the solenoid switches 170. Upon an abnormal voltage reading, the controller 150—through code executing in its on-board processor-sends a signal to a solenoid switch 170 to change the connection from a first connection to a second connection to isolate the defective battery (i.e., one displaying voltage abnormalities) from adjacent batteries 194. This circuit switching is further detailed in the context of a description of FIG. 5, found later in the disclosure.

In further embodiments of the present disclosure, the system 100 depicted in FIG. 1 also includes a sub-system hydrogen accumulation monitoring and ventilation. To this end, the system 100 includes a plurality of sensors e.g., 102, 104 arranged in fixed positions in the battery room (for example, in a grid or mesh). While two sensors are explicitly depicted and labeled, it should be understood that any number (n) of sensors can be employed. The sensors 102, 104 can be chemical sensors that generate electrical signals having an amplitude proportional to the hydrogen concentration to which the sensors are exposed. The output of the sensors 102, 104 is delivered to a hydrogen detector 105. The hydrogen detector 105 includes electronic components that are configured to determine whether the output received from the sensors 102, 104 indicate that a threshold hazardous hydrogen concentration has been reached at one or more parts of the battery room. As described below, when more than one sensor is deployed, the hydrogen detector can determine the location of whichever sensor(s) indicate that the threshold concentration has been reached. In certain embodiments, the first hydrogen gas concentration threshold is set at 1% of the total gas volume in the battery room. The first threshold can be set higher or lower, depending on the particular safety target of the facility; as such, the first threshold can be a hydrogen concentration set point with a higher granularity than “1%,” for instance either 0.8% of the total gas volume in the battery room or 1.2% of the total gas volume in the battery room.

Hydrogen detector 105 generates an output signal indicative of whether the threshold has been reached. For example, a signal of amplitude x indicates that the hydrogen concentration at or exceeding the threshold has been detected. If the hydrogen concentration reaches a second, higher threshold, for instance and merely as an example, 2% of total gas volume, the hydrogen detector can generate an output signal of amplitude y indicating that hydrogen concentration at the second threshold has been detected. In some implementations, the hydrogen detector 105 generates continuously varying outputs. While differential amplitude is one manner in which the hydrogen detector can communicate detection information and the severity of any hydrogen gas concentration in the air, other modalities such as such as pulse width, multiplexed outputs and so on can be used to convey the same detection information, depending on the circuitry employed.

The hydrogen detector 105 is communicatively coupled to a monitoring device 110 and to one or more integration relays 115 which receive the output of the hydrogen detector. In certain embodiments, the monitoring device 110 and integration relays comprise functional modules executed using program code on a single host computing device. In other embodiments, the monitoring device 110 and integration relay(s) 115 are functional modules executed using program code or application specific circuits on separate devices. The integration relay(s) 115 is(are) coupled to a communication system 116 and to one or more room alert devices 118, such as sound alarms, flashing lights and any suitable devices that can warn personnel that the room is potentially unsafe and should not be entered or should be entered with caution or while wearing protective gear. Additionally, the integration relay(s) 115 is(are) coupled to the battery stack(s) 120 and to a fan control system 125.

The monitoring tool 110 more generally comprises a device which receives the output of the hydrogen detector 105 via the at least one integration relay 115. If the signal received from the hydrogen detector indicates that the first threshold hydrogen concentration has been detected, the monitoring device 110 executes safety related processes via the integration relay 115. For instance, the monitoring device 110, under control of software or circuitry, may deliver one or more communications 117 such as calls, emails, or SMS messages through the communication system 116 to technical personnel that can respond to the hazardous condition. In some implementations, the delivered communications can be preconfigured in memory and accessed by the monitoring device 110 upon receipt of the signal indicating a hazardous hydrogen concentration from the hydrogen detector 105. The monitoring device 110 is also configured to generate an output signal to activate the alert devices 118 via the integration relay. The alert device 118 can be positioned on or near the door of the battery room and produce sound or lights to warn personnel in the facility. Integration relay 115 is also coupled to a battery charger 119 and can detect when the charger is in operation. The monitoring device 110 is configured to send commands to the fan control system 125 via integration relay 115.

As described in greater detail below, fan control system 125 operates at least two exhaust fans 126, 128. While two exhaust fans are explicitly labeled and depicted, the battery room can include more than two fans operated by the fan control system 125.

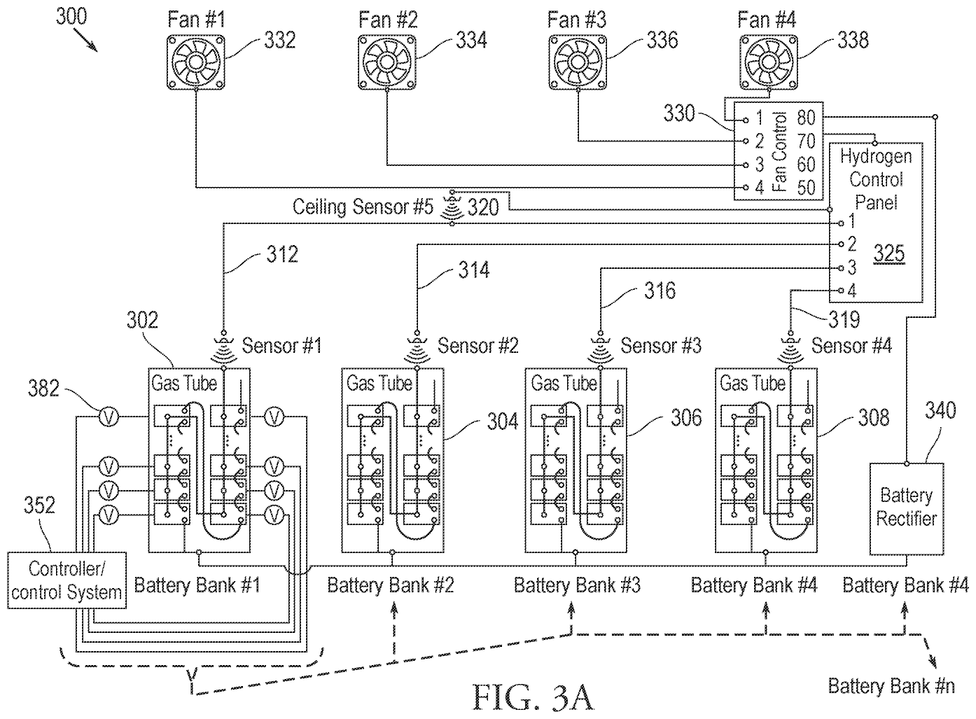

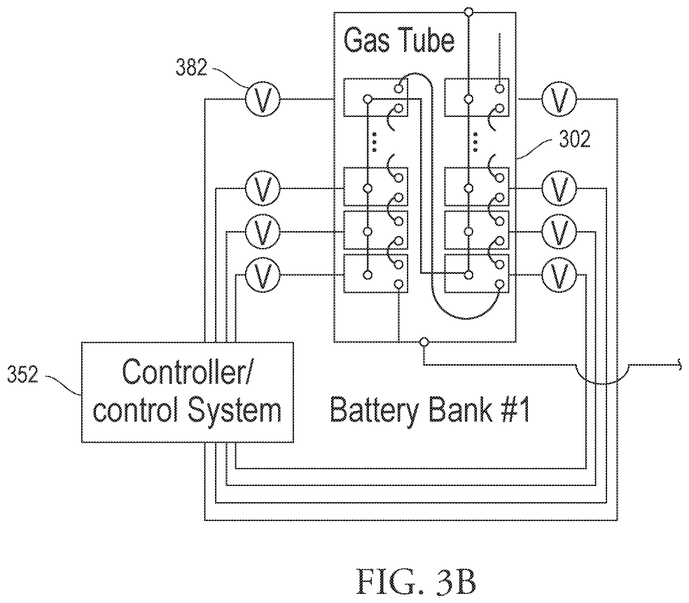

In an arrangement in which there are plural fans, there are at least two fan groupings, such that a first fan group and a second fan group can be operated in alternating sequence during “normal operation” and can be operated simultaneously during other operation modes in which hydrogen gas is to be evacuated more rapidly. Turning briefly to FIG. 3A, fans 332 and 336 can be in a first fan group and fans 334 and 338 can be in a second fan group such that two fans are operated during the “normal operation” mode and four fans or all fans can be activated and operated when hydrogen gas is to be evacuated.

In response to a command signal received from monitoring device 110, which is sent when a hydrogen concentration equal to or greater than the first threshold has been detected, the fan control system 125 switches the exhaust fans 126, 128 from alternate operation to simultaneous operation. More specifically, during normal, alternate operation, when non-hazardous conditions prevail, the fan control system 125 operates one of the exhaust fans 126, 128 and then switches to the other fan after a certain duration has elapsed, for example, 3 hours. In this manner, one of the exhaust fans is always operating during normal conditions. When the first threshold hydrogen concentration is detected, the fan control system overrides alternate operation and operates both fans 126, 128 at the same time which—for similarly sized and configured fans—doubles the rate at which hydrogen gas can be exhausted out of the battery room.

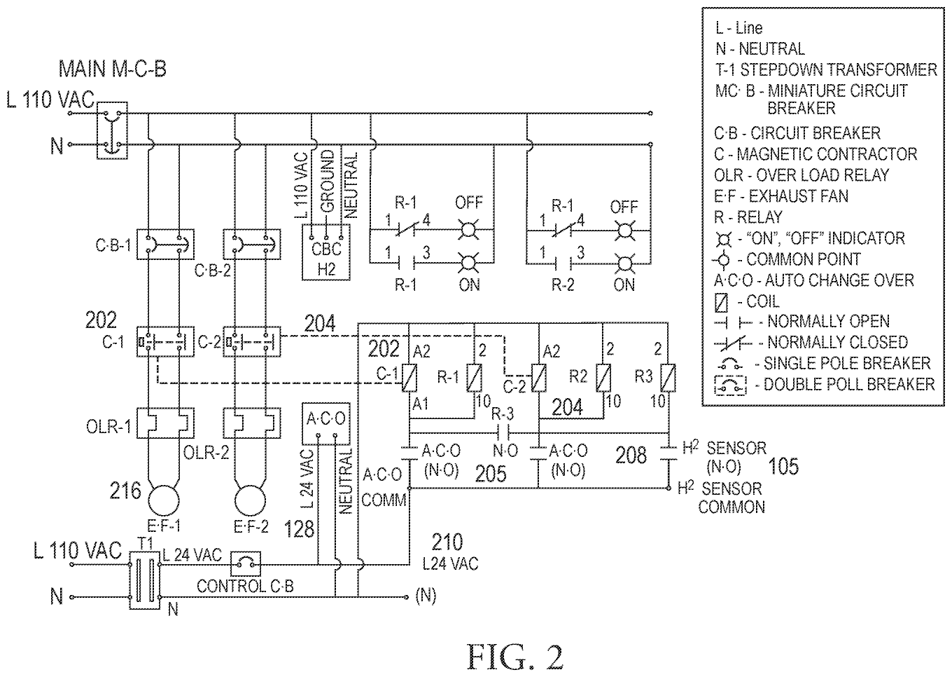

An exemplary circuit that can be used to implement the switchover operation of the fan control system is shown in FIG. 2, and an explanation of parts is illustrated in the legend of FIG. 2A. In FIG. 2, exhaust fans 126, 128 are controlled directly via respective contactors 202, 204 (both shown in two places in FIG. 2). A relay 205 with normally open (N.O.) contacts is coupled to a second relay with normally open contacts 208, which in turn, is coupled to and controlled by the hydrogen detector 105. Relay 205 is also coupled to contactors 202, 204. While relay 205 is in a normally open state, contactor 204 is not connected to power line 210 and is de-energized. If the hydrogen detector detects a hydrogen concentration above the first threshold, it changes the normally open point of relay 208 to normally closed (N.C.) which causes relay 205 to energize. When relay 205 energizes, it switches from normally open to normally closed (N.C.) which effectively connects both contactors 202, 204 to the power line, and triggers simultaneous exhaust fan operation. If the hydrogen level declines to less than 1% and the sensor alarm clears, then the relay 208 returns to a normally open position and the fans return to alternating mode operation.

The disclosed system also determines the precise location in the battery room at which a hazardous hydrogen has been detected. FIG. 3A is a schematic diagram of an exemplary battery and sensor deployment in a system for managing a battery room and isolating defective batteries according to the present disclosure. In the arrangement shown in FIG. 3A, a battery room 300 contains four battery banks 302, 304, 306 and 308. Hydrogen concentration sensors 312, 314, 316, 318 are positioned at gas tube outlets (“gas tube sensors”) of the respective battery banks 302-308, which, in this example, have a one-to-one relationship to respective battery banks. An additional hydrogen concentration sensor 320 is positioned on the ceiling of the room. All of the sensors 312, 314, 316, 318, 320 are communicatively coupled to and mapped onto a hydrogen sensor control panel 325 (which together with all of the sensors comprise the hydrogen detector in this embodiment). The sensor control panel 325 is also coupled to a fan control unit 330 which, in turn, is coupled to and controls operation of exhaust fans 332, 334, 336, and 338. The fan control unit 330 is further communicatively coupled to a battery rectifier 340 which is adapted to provide DC current to the battery packs 302-308. During operation, the exact location of a hydrogen release is determined by the activation pattern of the gas tube sensors as determined by the hydrogen control panel to which the sensors are mapped. In some embodiments, the fan control unit 330 is configured to activate simultaneous operation of at least two of the exhaust fans 332-338 when either 1) the battery charging is started 2) the ceiling sensor and one of the gas tube sensors or 3) two or more gas tube sensors indicate a hydrogen concentration at or above the first threshold.

FIG. 3B further an expanded view of a sub-system for monitoring batteries in a battery bank and isolating batteries exhibiting abnormal conditions according to an implementation of the present disclosure. In at least one embodiment, every battery within battery banks #1 through #4 (302, 304, 306, 308) in FIG. 3A are each communicatively connected to a controller, such as controller 352, though these connections are not depicted in FIG. 3A. Additionally, every battery within battery banks #1 through #4 are coupled through an electrical connection to a respective solenoid switch. In further aspects, each battery within the battery banks is connected to a voltmeter sensor, such as a voltmeter sensor 382. The voltmeter sensors are further communicatively connected to the controller 352. When the controller 352 senses any abnormality in a battery's voltage, the controller 352 it will send a signal to that battery's respective solenoid switch to change the connection from a first connection arrangement to a second connection arrangement, thus isolating the battery displaying voltage abnormalities.

In some methods and systems consistent with the present disclosure, the sub-system for battery monitoring and automatic self-isolation further comprises regular intervals of diagnostic checking performed by the controller 352 through code executing on a processor housed therein. These diagnostic checks are performed to validate the functionality of the solenoid switches upon isolation of a defective battery. A diagnostic check confirms the solenoid switch has successfully changed from a first connection to a second connection to isolate the defective battery. In some variations, a controller 352 is programmed and designated to conduct periodic voltage level assessments on adjacent batteries to the isolated defective battery. Such assessments help determine whether the isolation of the defective battery has impacted the functioning of adjacent batteries, with these assessments being recorded in computer memory housed within the controller 352 to facilitate proactive maintenance and minimize the risk of subsequent battery failures.

In further implementations, the controller 352 further comprises one or more redundancy systems, such as, for example, backup controllers 354, 356, and 358, communicatively connected to the same battery banks and batteries. In the event of a failure of the primary controller 352, the redundancy system maintains the capability to detect abnormal voltage levels and execute the isolation of defective batteries to ensure continuous operation of the isolation feature.

Returning to FIG. 1, if the monitoring device 110 receives a signal from the hydrogen detector 105, via the integration relays 115, which indicates that the hydrogen concentration has reached the second threshold, the monitoring device is configured to generate an output signal to activate the battery circuit breaker 120. Activation of the battery circuit breaker stops all current battery charging operations, which halts any additional hydrogen production in the battery room. In addition, when the second threshold concentration is detected, the monitoring device 110 is configured to escalate notifications and to alert management of a potentially serious safety hazard via notification system 130. The monitoring device 110 is configured, by circuitry or code executing in association therewith, to generate and provide a prescribed communication which can include at least one call, text message, email, or combination of the foregoing, to ensure that management is made aware of the hazard immediately. In one embodiment, the notifications are further configured to include information provided by the monitoring device 110 which identifies the battery bank that is releasing hydrogen and which specifies that battery bank's location in the battery room, based on information received from the hydrogen detector.

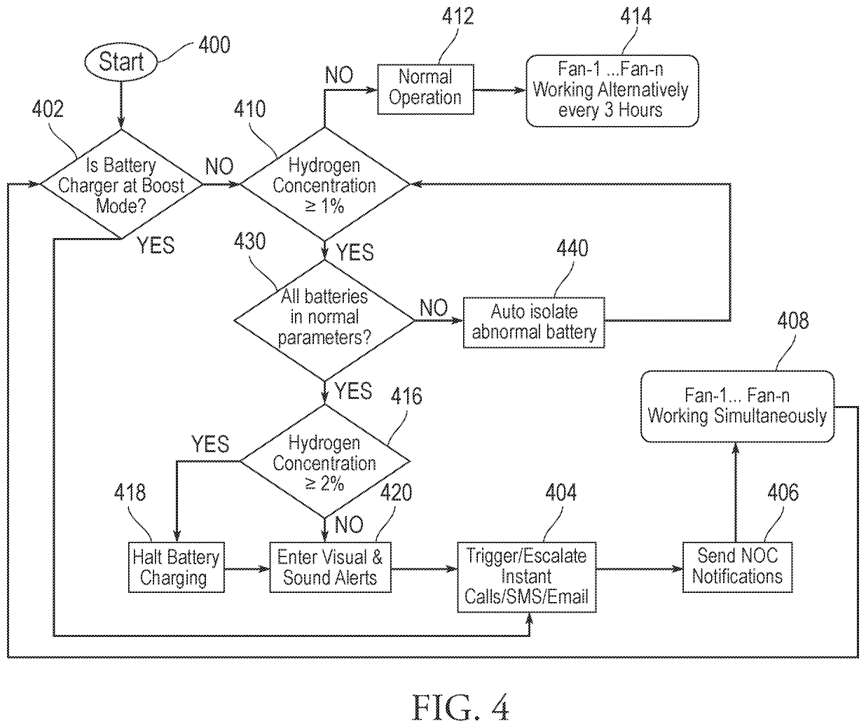

FIG. 4 is a flow chart of a method for managing a battery room and isolating defective batteries according to an embodiment of the present disclosure. The method steps can be performed, based on executable program code or circuitry, by the monitoring device 110 in combination with the integration relay(s) 115 and the controller 150, among other components and features. The method begins at step 400. In step 402, it is determined whether the battery charger is set to boost mode. In boost mode, battery chargers release hydrogen at an accelerated rate. Therefore, boost mode is treated like a hazardous hydrogen concentration as a precautionary measure. In certain implementations, the condition of the battery charger is detected by the monitoring device 110 which is coupled to the battery stacks and the battery rectifier 340 via the integration relays 115.

If it is determined in step 402 that the battery charger is in charger mode, then in step 404, the monitoring device triggers an escalation by generating one or more prescribed notifications. In step 406, the prescribed notification(s) is(are) sent to a technical field team or other personnel to begin remediation procedures. Additionally, in step 408, the integration relay delivers a command to the fan control unit to operate the exhaust fans in a second fan-operation mode in which several fans are operated simultaneously, and more specifically, more fans than in a first, normal operation mode are operated simultaneously, as long as the charger is in boost mode. Following step 406, the process cycles back to step 402. In further implementations, however, there is no step 402, for example, in a case where the batteries in question are not capable of a boost mode. In such implementations, the method proceeds directly from step 400 to 410.

If, in step 402, it is determined that the battery charger is not in charger mode, in step 410, the monitoring device 110 determines whether the output of hydrogen detector indicates that the hydrogen concentration is at or above first threshold concentration (e.g., 1%). If it is determined that the hydrogen concentration is below the first threshold, in step 412 at least one integration relay sets an internal operation mode flag to “normal operation.” In step 414, based on the “normal operation” setting, the monitoring device generates a command to the fan control system to operate the exhaust fans in alternating mode in which a first fan-operation mode is engaged, such as one in which a single fan in the battery room operates for a certain duration (for example, 2-4 hours) and then switches off at the same time another fan is activated.

If it is determined in step 410 that the hydrogen concentration is at or above the first threshold, the process branches to step 430. In step 430, the controller 150 monitors designated batteries in battery banks and/or battery rooms that make up the battery system of interest. The monitoring performed by controller 150 includes voltmeter sensors electrically connected to each battery within the battery banks and battery rooms. These voltmeter sensors are communicatively connected to the controller 150 to pass signals related to changes in a voltage condition of individual batteries within the battery system.

The voltmeter sensors 180 are electrically connected to the controller 150, which is programmed to monitor abnormal voltage conditions or parameters and to interface with solenoid switches 170 capable of isolating batteries exhibiting abnormal voltage parameters. Upon an abnormal voltage reading at step 430, the controller 150 at step 440—through code executing in its on-board processor—sends a signal to a solenoid switch 170 to change the connection from a first connection to a second connection to isolate the defective battery (i.e., one displaying voltage abnormalities) from adjacent batteries.

Once the battery exhibiting abnormal voltage parameters is isolated, the method cycles back from step 440 to step 410 again. After returning to step 410, the hydrogen concentration is measured against the first threshold concentration level once more. If at step 410 the hydrogen concentration remains above a first threshold concentration, then the method again proceeds to step 430, where the controller 150 again checks for abnormal voltage conditions in batteries.

If it is determined in step 430 that all batteries are operating within normal parameters and hydrogen concentration is at or above the first threshold, the process branches to step 416, in which the monitoring device determines whether the hydrogen concentration has reached the second threshold (e.g., 2%).

If it is determined, in step 416, that the hydrogen concentration is below the second threshold, in step 418, the monitoring device activates the alert devices to send visual and audio alerts to warn against entering the battery room. After step 418, the process returns to step 404, and the process continues as described above.

Returning to step 416, if it is determined that the hydrogen concentration is at or above the second threshold, in step 420, the monitoring device generates a command that halts the battery charging process and the fan-operation moves to the second fan-operation mode in which fans are operated simultaneously, and more fans are being operated than when in the first fan-operation mode which is only applicable to normal operation.

In the following step the process returns to step 418. After step 418 the process follows again with step 404, but this step is modified. Since the second threshold has been reached, there is an escalation in the notification process and prescribed notifications are generated and sent to management to indicate the presence of a possibly serious health hazard. After the hydrogen release is addressed, the monitoring device sends a command to the fan control system to resume normal (alternating) fan operation.

It is noted that the notifications sent to the technical field personnel preferably include information as to the specific battery bank at which hydrogen is being released. Notification regarding the location of the hydrogen release can save a great deal of time and effort since it removes the need for technical personnel to spend time ascertaining the location of the release.

FIG. 5 is a circuit diagram 500 of an exemplary embodiment of a system for isolating defective batteries in a battery bank according to the present disclosure. In FIG. 5, battery #2 is connected to batteries #1 (510) and #3 (530) through a solenoid switch 570. A voltmeter sensor is connected to battery #2 (520) and connected to the switch through a programmable logic controller 550, such as an Arduino controller. When the controller 570 senses an abnormality in the battery #2 voltage, the controller 570 then sends send a signal to the solenoid switch 570 to change the connection from connection 1 to connection 2 as illustrated in FIG. 5. This circuit wiring switch effectively opens the circuit to battery #2 (520), preventing further current from being drawn from the now-isolated battery #2 (520).

In one or more embodiments, circuits like circuit 500 can be implemented for every battery in every battery bank that site technicians desire to monitor. In some implementations consistent with the present disclosure, the sub-system for battery monitoring and automatic self-isolation further comprises regular intervals of diagnostic checking performed by the controller 550 through code executing on a processor housed therein. These diagnostic checks are performed to validate the functionality of the solenoid switches upon isolation of a defective battery. A diagnostic check confirms the solenoid switch has successfully changed from a first connection to a second connection to isolate the defective battery.

In some variations, a controller 550 is further programmed and designated to conduct periodic voltage level assessments on adjacent batteries to the isolated defective battery. Such assessments help determine whether the isolation of the defective battery has impacted the functioning of adjacent batteries, with these assessments being recorded in computer memory housed within the controller 550 to facilitate proactive maintenance and minimize the risk of subsequent battery failures.

In one general prophetic example of the present disclosure, the battery isolation and hydrogen ventilation sub-systems comprise a complete system. The battery isolation sub-system identifies any failure in batteries within battery banks (such as battery banks 302, 304, 306, and 308, depicted in FIG. 3A) based on many different characteristics such as the specific gravity, internal temperature or internal resistance of the batteries. Based on those readings, an abnormal battery will be fully isolated automatically by the battery isolation sub-system—using a circuit configuration like the one depicted in FIG. 5—in order to prevent hydrogen accumulation. In addition, the battery isolation sub-system will send a signal to the rectifier 340 depicted in FIG. 3A or to an additional circuit to reduce the voltage supply level to be compatible with the new voltage capability for a respective battery bank. In situations where the isolation of the battery does not eliminate hydrogen accumulation, the hydrogen ventilation sub-system begins operating automatically to accelerate the removal of the accumulated hydrogen within a respective battery bank until the concentration is reduced to below 1%. However, if the concentration exceeds 2%, the full battery bank (such as battery banks 302, 304, 306, and 308, depicted in FIG. 3A) will be isolated, and sound and visual alarms (such as alerts 118 in FIG. 1) will be activated in the site with one or a combination of automatically generated escalation calls, SMS messages, and emails.

In a second more specific prophetic example of the present disclosure, the battery isolation and hydrogen ventilation sub-systems still comprise a complete system. A battery bank typically has 24 wet-cell lead acid batteries within it. Each of the batteries are about 2 volts. A typical voltage operating range for the batteries is between about 2.33 and about 2.18 volts during float charging (the normal condition for batteries in communications rooms). A typical internal resistance operating range for the batteries is no more than about 135% of the internal resistance baseline. A typical internal temperature operating range for the batteries is between about 20 and about 40 degrees Celsius. A typical specific gravity range for the batteries is between about 1.23 to about 1.25 kg/l. The battery isolation sub-system identifies any failure in the batteries within battery banks (such as battery banks 302, 304, 306, and 308, depicted in FIG. 3A) based on many different characteristics such as the specific gravity, internal temperature or internal resistance of the batteries. Abnormalities in these characteristics manifest themselves as sensor reading fluctuations. Based on those readings, an abnormal battery will be fully isolated automatically by the battery isolation sub-system—using a circuit configuration like the one depicted in FIG. 5—in order to prevent hydrogen accumulation. In addition, the battery isolation sub-system will send a signal to the rectifier 340 depicted in FIG. 3A or to an additional circuit to reduce the voltage supply level to be compatible with the new voltage capability for a respective battery bank. In situations where the isolation of the battery does not eliminate hydrogen accumulation, the hydrogen ventilation sub-system begins operating automatically to accelerate the removal of the accumulated hydrogen within a respective battery bank until the concentration is reduced to below 1%. However, if the concentration exceeds 2%, the full battery bank (such as battery banks 302, 304, 306, and 308, depicted in FIG. 3A) will be isolated, and sound and visual alarms (such as alerts 118 in FIG. 1) will be activated in the site with one or a combination of automatically generated escalation calls, SMS messages, and emails.

The systems and methods herein offer advantages over known methods, for example those for ventilating battery rooms which employ two exhaust fans which operate alternatively in compliance with an instituted safety standard. In such conventional methods only one fan operates at a time regardless of the air condition in the battery room, aimed to ensure that the hydrogen concentration does not exceed about 1% of the total air volume of the battery room. The systems and methods herein overcome the risk of accumulated hydrogen which increases in proportion to the number of lead-acid batteries stored in the battery room, and hydrogen release can increase significantly during the charging and discharging process, as it includes as an object the capability to protect against the hydrogen gas accumulation beyond the 1% level. In addition, the disclosed method and system enables increased battery count within confined spaces. In addition, the disclosed method and system enables intensified charging and discharging cycles.

Additionally, the systems and methods herein take into account spatial distribution of gas concentrations within the room to promote even and effective ventilation, and prevents areas of higher concentration that may remain unaddressed as is known in passive ventilation systems, minimizing risk to equipment and any personnel who may need to enter the battery rooms. Moreover, such the systems and methods herein dynamically adapt to fluctuating hydrogen levels and failing to ensure a preemptive response to potential dangers, in contrast to reactive systems that only addressing the presence of hydrogen gas rather than its source.

Furthermore, the systems and methods herein enable identification and isolation of individual faulty batteries, which are potential contributors to hydrogen accumulation, in contrast to systems lacking this aspect which would leave battery rooms, particularly those situated in unmanned and remote locations, vulnerable to delayed response times in critical situations, risking personnel safety and system integrity.

Further, the systems and methods herein integrate communication measures to promptly notify operations centers and provide detailed alerts through various channels, such as visual, auditory, and electronic communications, during situations where immediate attention and subsequent action are crucial.

It is to be understood that any structural and functional details disclosed herein are not to be interpreted as limiting the systems and methods, but rather are provided as a representative embodiment and/or arrangement for teaching one skilled in the art one or more ways to implement the methods.

It is to be further understood that like numerals in the drawings represent like elements through the several figures, and that not all components and/or steps described and illustrated with reference to the figures are required for all embodiments or arrangements.

As used herein, “about” means within a margin of less than or equal to plus or minus 1, 2, 5 or 10% of the compared value.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Terms of orientation are used herein merely for purposes of convention and referencing, and are not to be construed as limiting. However, it is recognized these terms could be used with reference to a viewer. Accordingly, no limitations are implied or to be inferred.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

The subject matter described above is provided by way of illustration only and should not be construed as limiting. Various modifications and changes can be made to the subject matter described herein without following the example embodiments and applications illustrated and described, and without departing from the true spirit and scope of the invention encompassed by the present disclosure, which is defined by the set of recitations in the following claims and by structures and functions or steps which are equivalent to these recitations.

What is claimed is:

1. A method of managing a battery system in a battery room, comprising:
continuously monitoring a voltage condition of individual batteries within the battery system;
automatically isolating a defective battery from the battery system upon detection of abnormal voltage levels through a controller,
wherein the controller sends a signal to a solenoid switch to change the connection from a first connection to a second connection to isolate the defective battery from adjacent batteries;
executing the isolation of the defective battery based on the abnormal voltage levels sensed by a voltmeter sensor attached to the respective battery,
wherein the sensor communicates detected abnormalities to the controller, and
wherein the controller interfaces with the solenoid switch;
detecting a hydrogen concentration in the battery room;
determining whether the hydrogen gas concentration is at or above a first threshold concentration;
activating two or more exhaust fans to ventilate the battery room simultaneously when the hydrogen gas concentration is at or above the first threshold;
identifying a location in the battery room at which hydrogen is being released;
determining whether the hydrogen gas concentration is at or above a second threshold concentration higher than the first threshold concentration;
halting charging of batteries in the battery room when the hydrogen gas concentration is at or above the second threshold; and
operating the two or more exhaust fans one at a time when the hydrogen gas concentration falls below the first threshold.

2. The method of claim 1, further comprising the step of conducting a diagnostic check to validate the functionality of the solenoid switches upon isolation of a defective battery, wherein the diagnostic check confirms the solenoid switch has successfully changed from a first connection to a second connection to isolate the defective battery.

3. The method of claim 1, wherein the controller comprises one or more redundancy systems, wherein in the event of a failure of the primary controller, the redundancy system maintains the capability to detect abnormal voltage levels and execute the isolation of defective batteries to ensure continuous operation of the isolation feature.

4. The method of claim 1, further comprising the step of conducting periodic voltage level assessments on adjacent batteries to the isolated defective battery,
wherein these assessments help determine whether the isolation of the defective battery has impacted the functioning of adjacent batteries, with these assessments being recorded to facilitate proactive maintenance and minimize the risk of subsequent battery failures.

5. The method of claim 1, wherein the batteries in the battery room are about 2-volt batteries.

6. The method of claim 5, wherein there are 24 batteries in each battery bank.

7. The method of claim 1, further comprising:
determining whether any batteries in the battery room are currently being charged; and
wherein the step of activating the two or more exhaust fans to ventilate the battery room simultaneously activates the two or more exhaust fans if the batteries are determined to be in a state of presently being charged or if the hydrogen gas concentration is at or above the first threshold concentration.

8. The method of claim 1, further comprising activating at least one of a sound and a visual alert when the hydrogen gas concentration is at or above the first threshold to warn personnel against entrance into the battery room.

9. The method of claim 1, wherein the battery room contains a plurality of battery banks and a plurality of hydrogen sensors, at least one of the plurality of hydrogen sensors being positioned at gas outlets of each of the plurality of battery banks, and wherein the location at which hydrogen is being released is determined based on which of the plurality of hydrogen sensors in the battery room detects an elevated hydrogen concentration.

10. The method of claim 9, wherein the plurality of hydrogen sensors further includes a ceiling sensor, and the step of determining whether the hydrogen gas concentration is at or above a first threshold concentration includes detecting a hydrogen concentration at or above the first threshold at a) two of the plurality of hydrogen sensors positioned at gas outlets of the battery banks, or b) at one of the plurality of hydrogen sensors positioned at gas outlets of the battery banks and at the ceiling sensor.

11. The method of claim 1, further comprising generating a notification and providing the notification to personnel when the hydrogen gas concentration is at or above the first threshold.

12. The method of claim 11, wherein the notification indicates the identified location in the battery room at which hydrogen is being released.

13. A system for managing a battery system in a battery room and isolating defective batteries, comprising:
a plurality of battery banks positioned in the battery room containing one or more batteries;
a controller configured to monitor the voltage of individual batteries within the battery banks;
a plurality of solenoid switches, wherein each solenoid switch is connected to at least two batteries;
a plurality of voltmeter sensors, each voltmeter sensor being associated with a respective battery and coupled to the controller; and
a control system coupled to the controller and to the solenoid switches for facilitating the isolation of a defective battery,
wherein the controller is operative to receive output from the voltmeter sensors indicating a voltage condition of each battery and to send a signal to respective solenoid switches to isolate a defective battery by changing the connection between the defective battery and adjacent batteries should an abnormal voltage be detected; and
a plurality of exhaust fans positioned in the battery room;
a plurality of hydrogen sensors, at least one of the plurality of hydrogen sensors positioned adjacent to each one of the plurality of battery banks;
a hydrogen detector coupled to the plurality of hydrogen sensors;
a monitoring device coupled to the hydrogen detector and to the plurality of exhaust fans;
wherein the hydrogen detector is operative to receive output from the plurality of hydrogen sensors and to generate a signal indicating a hydrogen concentration detected by the plurality of hydrogen sensors, and
wherein the monitoring device is configured to operate a fan control system to activate two or more of the plurality of exhaust fans to operate simultaneously upon receipt of a signal from the hydrogen detector indicating that the hydrogen concentration is at or above a first threshold,
thereby reducing the chance of hydrogen accumulation and, if the battery isolation does not control the hydrogen level and it reaches 1% or more, causing the monitoring device to activate the plurality of exhaust fans.

14. The system of claim 13, further comprising diagnostic functionality incorporated into the control system for validating the operation of the solenoid switches upon isolation of a defective battery, wherein the diagnostic functionality is configured to verify that the solenoid switch has successfully changed connections to isolate the defective battery.

15. The system of claim 13, wherein the controller includes one or more backup redundancy systems designed to assume control in the event of a primary controller failure, wherein the redundancy systems are equipped with circuitry and programming to detect abnormal voltage levels and to control the solenoid switches for the isolation of defective batteries.

16. The system of claim 13, further comprising voltmeter sensors to conduct voltage assessments on the batteries adjacent to the isolated defective battery, wherein the control system is configured to record the outcomes of these assessments.

17. The system of claim 13, further comprising a battery charger coupled to the monitor, wherein the monitor is configured operate the fan control system to activate two or more exhaust fans to ventilate the battery room simultaneously if the battery charger is presently charging a battery bank or if the hydrogen gas concentration is at or above the first threshold concentration.

18. The system of claim 17, wherein the fan control system activates the two or more exhaust fans to ventilate the battery room simultaneously when the battery charger operates in a boost mode.

19. The system of claim 13, wherein the monitoring device is configured to identify which of the plurality of battery banks is releasing hydrogen gas based on the output of the hydrogen detector when the hydrogen concentration is determined to be at or above the first threshold.

20. The system of claim 13, further comprising at least one of a sound alarm and a visual alarm positioned near an entrance to the battery room, wherein the monitoring device is configured to activate the sound alarm or visual alarm upon receipt of a signal from the hydrogen detector indicating that the hydrogen concentration is at or above the first threshold.

21. The system of claim 13, further comprising a battery charger breaker coupled to the monitoring tool and the plurality of battery banks, wherein the hydrogen detector is operative to output a signal indicating whether the hydrogen gas concentration is at or above a second threshold concentration higher than the first threshold and the monitoring device is configured to activate the battery charger breaker to halt charging of plurality of battery banks.

22. The system of claim 21, wherein the first threshold concentration is 1 percent concentration by volume concentration and the second threshold is 2 percent concentration by volume.

23. The system of claim 17, wherein the plurality of hydrogen sensors further includes a sensor positioned on a ceiling of the battery room, and the hydrogen detector is configured to indicate that the hydrogen concentration is at or above the first threshold if 1) at least two of the hydrogen sensors positioned adjacent to the battery banks or 2) at least one of the hydrogen sensors positioned adjacent to the battery banks and the ceiling sensor detect a hydrogen concentration at or above the first threshold.

24. The system of claim 13, wherein the monitoring device is configured to activate one of the plurality of exhaust fans at a time when output hydrogen detector indicates that the hydrogen concentration is below the first threshold.

25. The system of claim 18, wherein the monitoring device is configured to generate and provide notifications to personnel including the identified location of the hydrogen release.

26. The system of claim 13, wherein the batteries in the battery room are about 2-volt batteries.

27. The system of claim 26, wherein there are 24 batteries in each battery bank.
